(19) United States
(12) Patent Application Publication
(10) Pub. No.: US 2006/0237852 A1
(43) Pub. Date: Oct. 26, 2006

(54) Semiconductor device in which LSI chip is arranged on package substrate in flipped condition and substrate wiring designing method

(75) Inventors: Mitsumi Ito, Nagaokakyo-shi (JP); Shinya Tokunaga, Kyoto-shi (JP)

Correspondence Address: PANASONIC PATENT CENTER;c/o MCDERMOTT WILL & EMERY LLP, 600 13TH STREET, NW, WASHINGTON, DC, 20005-3096, US

(73) Assignee: MATSUSHITA ELECTRIC INDUSTRIAL CO., LTD.

(21) Appl. No.: 11/410,050

(22) Filed: Apr. 25, 2006

(30) Foreign Application Priority Data
Apr. 25, 2005 (JP) P2005-126063

(51) Int. Cl. H01L 23/48

(52) U.S. Cl. 257/774

(57) ABSTRACT

In the LSI design stage, areas indicating the circuits that handle a minute signal are formed as wiring excluding area patterns. The coordinates of the wiring excluding area patterns in a state that the LSI chip is flipped are calculated, and the substrate design tool is caused to recognize such coordinates. No wiring is provided in the recognized wiring excluding areas when the substrate wirings are designed by the substrate design tool. As a result, the electric coupling between the substrate wirings and the minute signal circuit can be suppressed, and also a malfunction of the circuit can be prevented.

### BACKGROUND OF THE INVENTION

1. Field of the Invention

The present invention is the designing/manufacturing technology relating to a measure to reduce noises of a semiconductor product of a flip-chip type in which an LSI chip is bonded onto a package substrate to oppose their surfaces to each other.

2. Description of the Related Art

A higher density in the field of system LSI is advanced. The flip-chip type package in which an LSI is mounted on a package substrate facedown becomes the main stream of the system LSI instead of the lead frame type package.

In the package substrate design, connections from input/output pads of an LSI chip to a package substrate and a wiring design in the package substrate are carried out based on position information of input/output pads of an LSI chip and a chip size without regard to a circuit configuration of the LSI chip. Therefore, the substrate wiring of the package substrate can be provided without restriction in the package substrate area in the LSI chip is positioned, i.e., the area that is covered with the LSI chip.

As the prior art associated with the present invention, there is Patent Literature 1. In Patent Literature 1, in the configuration in which additional wirings are provided on a chip surface to connect to the substrate, a configuration in which the additional wirings are arranged to avoid minute signal circuit areas is disclosed. However, since JP-A-2000-58548 discusses such configuration on the assumption that the additional wirings are provided on the chip surface, such configuration can be designed closely by the chip design tool. Therefore, when the proper signals should be output from the proper terminals via the substrate wirings on the package substrate, the substrate wirings cannot avoid the minute signal circuit areas because the chip design tool and the package design tool are the independent tool respectively. Thus, it is possible that a malfunction of the LSI is brought about.

However, in the package substrate designing approach in the prior art, in the case of the flip-chip type package, the face-down structure in which respective surfaces of the package substrate and the LSI chip are faced to each other is provided since the bumps formed on the input/output pads of the LSI chip are jointed directly to the electrode terminals of the package substrate. Since the face-down structure has a physical close distance between the package substrate and the LSI chip internal circuit rather than the face-up structure, in some cases the electric coupling is caused to bring about a malfunction of the LSI when the package substrate wiring is formed in the area to which the LSI chip opposes. In particular, the circuit handling a minute signal in an analog fashion is readily subject to the influence of cross talk, which causes generation of a jitter noise. In this case, a reduction of the cross talk can be attained by setting the wiring inhibit area in all areas of the package substrate to which the LSI chips oppose when the package substrate wirings are designed, but such approach is not practical because the wiring resource is conspicuously reduced. Also, it is possible technically to increase the number of substrate wiring layers and utilize an uppermost layer like a wall, but such a problem arises that a substrate cost is increased.

In order to overcome the above problem, in the present invention, the analog or memo block circuit areas of the LSI chip, which are operated by a minute signal, are set previously as the substrate wiring inhibit area in LSI design data, and then the set data are synthesized with the package design data not to provide the wirings in the wiring inhibit area when the substrate wirings are provided actually. Accordingly, the wirings are inhibited to restrict the wiring inhibit area to the package substrate areas that face to the critical area in the LSI chip. The wiring inhibit area is suppressed in the smaller space, a noise reduction can be achieved not to increase the number of substrate wiring layers, and a malfunction of the LSI can be prevented.

Since the package substrate design is applied based on the above method, the substrate wirings can be designed to avoid the package substrate area opposing to the circuit, which handles a minute signal in the LSI chip, and also a reduction of the cross talk and a generation of the jitter noise can be suppressed. Therefore, a high-quality product not to cause a malfunction can be manufactured.

### BRIEF DESCRIPTION OF THE DRAWINGS

FIG. 1 is a flowchart of an embodiment of the present invention.

FIG. 2 is a view showing an LSI chip of the present invention.

FIG. 3 is a view showing an inverted LSI chip of the present invention.

FIG. 4 is a view showing a configuration in which a package substrate and the inverted LSI chip of the present invention are superposed.

FIG. 5 is a view showing the LSI chip that is subject to substrate wirings by the present invention and the package substrate.

FIG. 6 is a view showing the package substrate of the present invention.

FIG. 7 is Another flowchart of the embodiment of the present invention.

FIG. 8 is a view showing design environments applied to execute a package substrate designing method of the present invention.

### DESCRIPTION OF THE PREFERRED EMBODIMENTS

An embodiment of the present invention will be explained with reference to the drawings hereinafter.

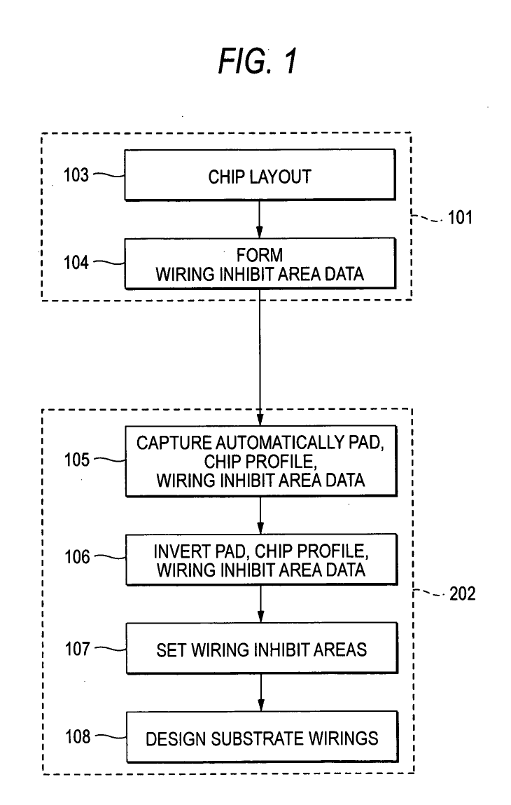

FIG. 1 shows a flowchart of a chip and package designing method according to an embodiment of the present invention. Then, explanation will be made of an embodiment of the present invention hereinafter with referring to FIG. 1 and other Figures as the case may be.

The designing method of the present embodiment is carried out by two design tools of a chip design tool 101 used to design the LSI chip and a package design tool 102 used to connect the LSI chip and the package substrate via the wiring.

First, the chip design tool executes a chip layout step 103. When the chip layout is designed in the LSI design, the method of first designing the circuit blocks that perform a predetermined function respectively, then placing these circuit blocks and macrocells (memory such as SRAM, or the like, CPU, and the like) a basic structure of which has already been designed respectively in the chip, and then connecting the circuit blocks and the macrocells via the wirings is commonly used. The design of the circuit block is carried out on a custom-made basis or carried out based on the automatic placement/routing using standard cells. The latter is common at present because an integration degree in the LSI chip is increased. In many cases the designed chip layouts are given as the data using the GDS two-stream format. This GDS two-stream format represents respective constituent elements of the LSI chip (metal conductor containing the gate of the transistor, diffusion layer, and the like) as rectangular data, and outermost profiles of the circuit blocks and the macrocells can also be defined as the rectangular data.

Then, the chip design tool executes a wiring inhibit area data forming step 104. The wiring inhibit area is defined as the area to which the substrate wiring cannot be laid to oppose when the LSI chip is placed on the substrate. Here, the circuit blocks such as the analog circuit block, the memory block, and the like, which deal with a minute signal, are decided as the wiring inhibit area. The wiring inhibit area is defined as the layer of the GDS two-stream format. This operation can be accomplished by surrounding the outermost profile of the circuit block to be set as the wiring inhibit area with a simple figure pattern while using a function of the chip design tool. It is desired that the figure pattern should be defined by the dedicated layer number to make the identification in the later step possible.

In this case, the wiring inhibit area is not limited to the analog and the memory, and the area that is readily subject to the influence of cross talk may be designated arbitrarily by the designer's intention. In the case where the designer wishes to designate any area as the wiring inhibit area instead of the circuit block unit, if the figure pattern is formed in any place on the LSI chip data, the layer number of the figure pattern can be utilized as it is in the later step as the wiring inhibit area.

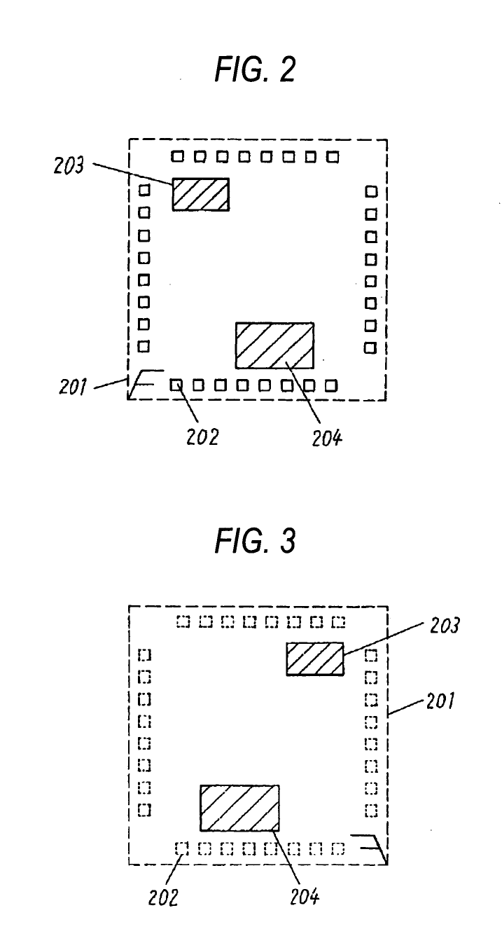

FIG. 2 shows chip layout data in which the wiring inhibit areas are set. The shaded area in an LSI chip 201 indicates that such area is defined as the wiring inhibit area. An analog circuit block 203 and a memory block 204 are defined as the wiring inhibit area respectively. Also, an input/output pad 202 and other circuit blocks (not shown) not corresponding to the wiring inhibit area are defined in the chip layout data. The chip layout data are converted in advance into the ASCII text format by the chip design tool 101 and utilized such that compatibility can be held between the chip design tool 101 and the package design tool 102.

In this case, there is the interface via which the GDS stream format can be captured directly into the package design tool. For this reason, if a function capable of recognizing the input/output pads, the LSI chip outer profiles, and the wiring inhibit areas as the GDS stream format as they are is provided, the conversion into the ASCII text format is not always needed.

The above layout data constitute the inputs to the package design tool 102 as the tool for the later step. In the package design tool, first a pad, chip profile, wiring inhibit area data automatically capturing step 105 is executed. In this step, the layout data converted into the ASCII text format are received as the input, then LSI chip outer size, input/output pad coordinates, and signal information being input/output into/from respective input/output pads are captured, as in the prior art, and in addition coordinates of the wiring inhibit areas formed by the wiring inhibit area data forming step 104 are captured.

Then, actually the LSI chip is flipped and mounted on the substrate. Therefore, in a pad, chip profile, wiring inhibit area data inverting step 106, the coordinates of respective chip layout data are inverted. An inverted state of the chip layout data is shown in FIG. 3.

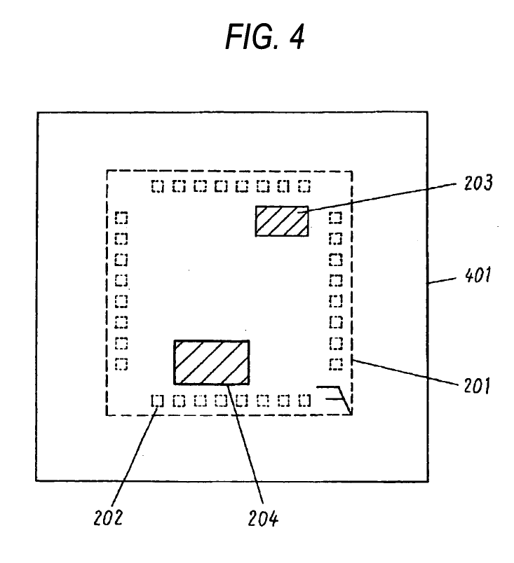

Then, in a wiring inhibit area setting step 107, the package substrate data prior to the package wiring and the inverted chip layout data are combined together. At this time, when origins of the LSI chip and the package substrate are deviated mutually, their positions are aligned by shifting the coordinates. As a result, the coordinates of the area on the substrate opposing to the inverted wiring inhibit area are set as the wiring inhibit area in the package design tool 102. A state in which the chip layout data of the LSI chip are inverted and superposed on the substrate data prior to the wiring is shown in FIG. 4. The flipped LSI chip 201 is mounted onto a package substrate 401.

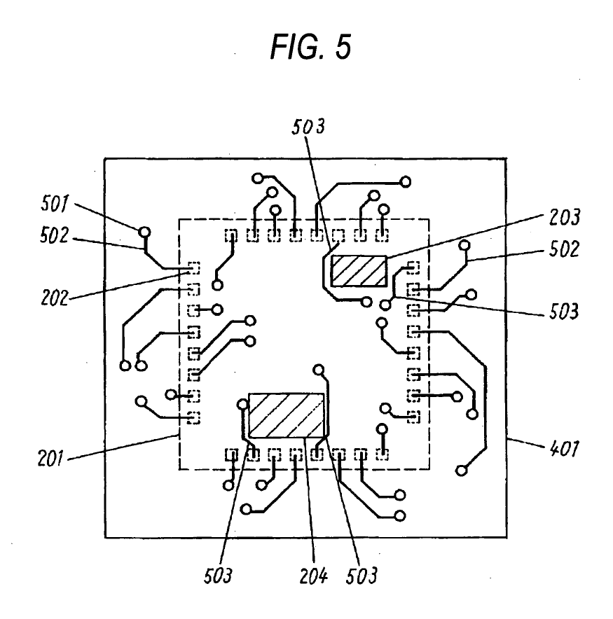

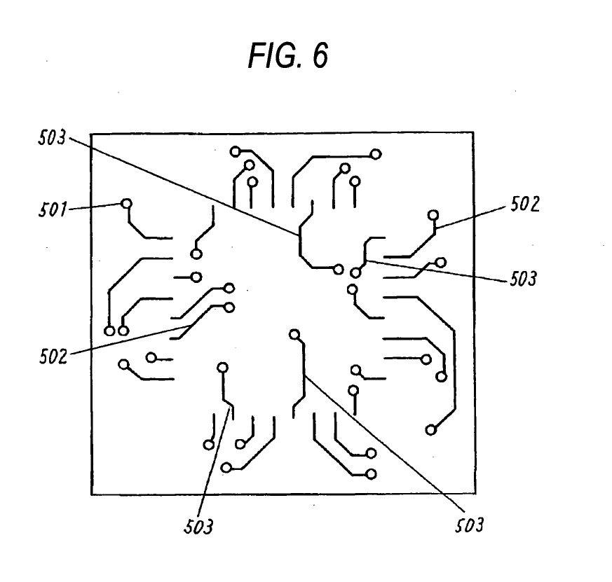

Finally, in a substrate wiring designing step 108, the substrate wiring is carried out. Here, the substrate wiring is executed by receiving the input/output pad coordinates of the LSI chip and the LSI chip outer size such that signals output from necessary input/output pads are supplied to necessary vias (package terminals). Of course, the wiring design is controlled such that the substrate wiring is not wired in the wiring inhibit area. A state where the substrate wirings are completed is shown in FIG. 5. As shown in FIG. 5, normally a package substrate wiring 502 is wired via a shortest route from a via 501 to the input/output pad 202 as the target. However, since the positions opposing to the analog circuit block 203 and the memory block 204 are defined as the wiring inhibit area, a substrate wiring 503 to be wired in vicinity of the wiring inhibit area must be wired to avoid the analog circuit block 203 and the memory block 204 as the wiring inhibit area. As a result, the circuit blocks such as the analog circuit block, the memory block, and the like, which are easily subject to the influence of the cross talk, can be protected from the influence of the substrate wiring. In this case, only the wiring substrate data picked up from the package substrate are shown in FIG. 6.

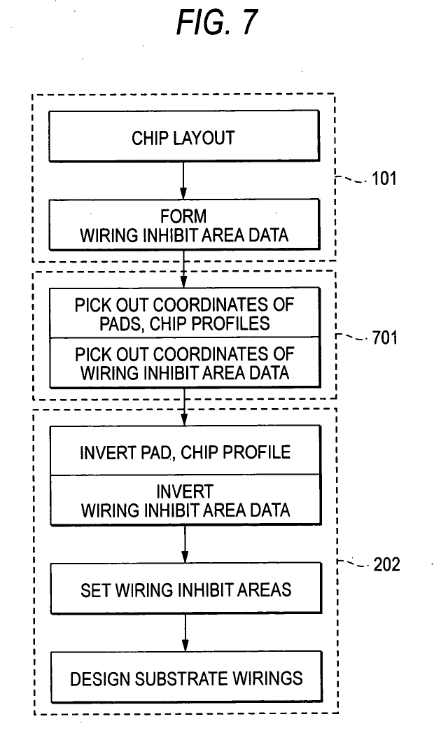

Then, when the chip design tool has no converting function into the ASCII text format and also the package design tool has no function of handling the GDS stream format, the present invention can be embodied by converting the GDS stream format into the ASCII text format while using the original tool such as the GDS stream format analyzing tool, and the like. A flowchart in that case is shown in FIG. 7. As an operation of a particular original tool 701, the coordinates of the wiring inhibit areas, which are formed by defining the layer numbers by the chip design tool 101, on the LSI chip and the coordinates of the pads and the chip profiles are extracted in the ASCII text by using the layer numbers as keys. The extracted data are input into the package design tool as the later step in the ASCII text format, and then the inversion of the coordinates is carried out because the LSI is flipped. Since the present invention is carried out via the original tool 701 as described above, the present invention is applicable to the existing tool.

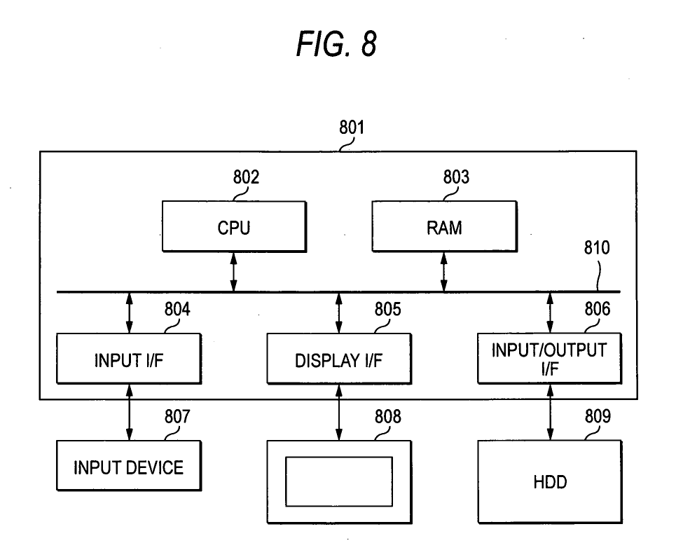

Finally, design environments required to execute the package substrate designing method of the present invention will be explained hereunder. FIG. 8 shows the design environments in which the present invention is applied. A design system 801 includes a CPU 802, a RAM 803, an input I/F 804, a display I/F 805, and an input/output I/F 806. All the devices are connected via a bus 810, and can get into data communication with each other. The input I/F 804 is connected to an input device 807 that accepts the input from the designer. As an example of the input device 807, there is the keyboard or the mouse. The display I/F 805 is connected to a display device 808 used when the designer peruses the layout data, and the like. As an example of the display device 808, there is the CRT display or the liquid crystal display. The input/output I/F 806 is connected to a HDD (Hard Disk Drive) 809. The chip design tool 101, the package design tool 102, or the original tool 701 are stored in the HDD 809 as the program. Also, the data in the middle of design or the final layout data, if necessary, are saved in the HDD 809. The CPU 802 processes the program stored in the HDD 809 as the tool, based on the user's instruction input via the input I/F 804. In the process of the program, the RAM 803 is utilized as the working area and the writing/reading of the data into/from the RAM are executed at a required timing. The designer does not explicitly instruct the writing/reading of the data into/from the RAM 803, but executes the writing/reading into/from the RAM entirely in compliance with the program stored in the HDD 809. Also, the designer can check the design stage by the display device 808. The layout data generated finally are output to the HDD 809, and the design is ended.

The package substrate designing approach according to the present invention can take account of position information of the circuit that handles the minute signal of the LSI chip, and is useful as the measure to reduce noises.

What is claimed is:

1. A semiconductor device, comprising:
a package substrate, having a plurality of vias and executing input/output of signals into/from an external device; and
an LSI chip, arranged on the package substrate in a flipped condition;
wherein the LSI chip has a plurality of circuit blocks and a plurality of input/output pads to input/output signals into/from the package substrate; and
substrate wirings to connect the input/output pads and the vias on the package substrate are wired to detour an area that opposes to a predetermined circuit block out of the plurality of circuit blocks.

2. The semiconductor device according to claim 1, wherein the predetermined circuit block is an analog circuit block to output an analog signal.

3. The semiconductor device according to claim 1, wherein the predetermined circuit block is a memory block to store data.

4. A substrate wiring designing method of connecting a package substrate, which executes input/output of signals into/from an external device, and an LSI chip, which is arranged on the package substrate in a flipped condition, via substrate wirings on the package substrate, comprising the steps of:
defining previously any area in the LSI chip as a wiring inhibit area; and
providing the substrate wirings to detour the wiring inhibit area.
